(19) United States
(12) Patent Application Publication
(10) Pub. No.: US 2011/0146754 A1
(43) Pub. Date: Jun. 23, 2011

(54) SOLAR CONVERSION SYSTEM HAVING SOLAR COLLECTOR FOR FORMING A TRANSPOSED IMAGE

(75) Inventor: James E. Vander Mey, Dunnellon, FL (US)

(73) Assignee: brightLeaf Technologies, Inc., Montrose, CO (US)

(21) Appl. No.: 12/974,963

(22) Filed: Dec. 21, 2010

Related U.S. Application Data
(60) Provisional application No. 61/289,216, filed on Dec. 22, 2009.

(51) Int. Cl. H01L 31/0232; H01L 31/052

(52) U.S. Cl. 136/246; 136/259

(57) ABSTRACT

A solar collector for concentrating reflected solar energy into an image that is converted into electricity. The collector is configured so that solar energy reflecting from regions of the collector farthest from the image is directed towards the middle region of the image. Alternatively, one or more segments of the collector can be configured to form a corresponding discrete portion of the image; the solar energy forming the portion of the image can be inverted from the solar energy reflecting from the one or more segments. Optionally, the portions created by the one or more segments can overlap.

### CROSS REFERENCE TO RELATED APPLICATIONS

This application claims priority to and the benefit of co-pending U.S. Provisional Application Ser. No. 61/289,216, filed Dec. 22, 2009, the full disclosure of which is hereby incorporated by reference herein.

### FIELD OF THE INVENTION

The present disclosure relates in general to a solar conversion system that collects and concentrates solar energy, then converts the collected/concentrated energy into electricity. More specifically, the present disclosure includes a solar conversion system having a concentrating solar collector that form an image of reflected rays, where the arrangement of the reflected rays forming the image is transposed from their relative position when reflecting from the collector.

### DESCRIPTION OF PRIOR ART

Solar conversion systems convert electromagnetic energy to electricity by exposing a photovoltaic cell to a light source, such as the sun. Photons in the electromagnetic energy strike the photovoltaic cell that in turn creates electrical potential differences therein. The potential differences induce an electrical current flow through the cell, thereby forming an electrical energy source. Some solar cells are exposed directly to the light source without intensifying the light. Other conversion systems concentrate light onto a photovoltaic cell using reflective solar collectors. Typically, the concentrating solar collectors have a curved reflective surface that concentrates the light onto the solar cell. The curvature may be along a single axis or along both axes of the collector. The reflective surface may be parabolic. The area where the light concentrates can be along the mid point or axis of the reflective surface or can be off set from the axis.

One example of a prior art solar concentration system 10 is illustrated in a side perspective view in FIG. 1. The system 10 includes a rectangular-shaped collector 12 having a concave reflective surface facing a light source (not shown). Light rays 14 from the light source contact and reflect from the reflective surface as reflected rays 16 that are directed to an area offset from the midpoint of the collector 12. An X-Y-Z axis with an Origin O is provided; for the purposes of illustration, the collector 12 has a width that is along the Y-axis and a length along the edge of the collector 12 in a direction transverse to the Y-axis. Coordinates are provided adjacent each corner of the collector 12 that illustrate spatial locations with respect to the Origin of the XYZ axis. The collector 12 is recumbently inclined, having one end (the upper end) of the collector 12 disposed at a larger value of Z on the Z axis than its opposite end. For reference, the end of the collector 12 where X=0 and Z=1 is referred to as the upper end 13 and the end of the collector 12 where X=1 and Z=0 is referred to as the lower end 15.

The reflected rays 16 converge at an area that is offset with respect to the X axis, but substantially aligned midway along the collector 12 in the Y axis; an image 18 is formed at the area where the reflected rays 16 converge. A solar cell (not shown) is typically included and positioned to coincide with the image 18. The image 18 mirrors the collector 12; that is, the reflected ray 16 originating from location (0,0,1) on the collector 12 is directed to the corresponding location (0,0,1) shown on a corner of the image 18. In similar fashion, the remaining corners of the collector 12 couple with corresponding corners on the image 18. Since the image 18 is off-axis from the collector 12, the rays 16 from locations (0,0,1) and (0,1,1) are longer than the rays 16 from locations (1,0,0) and (1,1,0). The disparity in length of the rays 16 directed from different spatial locations on the collector 12 can move and/or distort the shape of the reflected image 18 with changes in the relative orientation between the collector 12 and the sun.

Illustrating a moved/distorted image, an off-center solar ray 20 is shown contacting the corners and unaligned from ray 14 by angle θ. Off-center ray 20 reflects from the surface of the collector 12 as reflected off center rays 22. The reflected off-center rays 22 that reflect from points (0, 0, 1) and (0, 1, 1) are unaligned from the aligned reflected ray 16 by an angle θ₁. The reflected off-center rays 22 that reflect from the collector 12 at points (1, 0, 0) and (1, 1, 0) differ from the aligned rays 16 that reflect from those same points by an angle of θ₂. The reflected off-center rays 22 converge and form a concentrated off-center image 24 different in location, size, and shape from the aligned image 18. The reflected off-center rays 22 directed from portions of the collector 12 at the upper end, or where the X value is 0, are longer than the reflected off-center rays 22 that reflect from the end of the collector 12 where the X value is 1. Accordingly, the portion of the image 24 formed by the longer off-center rays 22 experiences more movement and distortion than the portion of the image 24 formed by the shorter reflected off-center rays 22. Depending on the overall size of a solar cell used in this system, some portion of the image 24 may not coincide with the solar cell surface, thereby reducing performance and efficiency of the system. The distortion may also increase flux density within some portion of the image 24 to a value that exceeds operational limits of a solar cell.

In another example of a collector 12 misaligned with the sun, off-center solar rays 26 contact the reflective surface of the collector 12 that are unaligned by an angle of phi Φ from the aligned solar ray 14 to form an off-set image 30. In this unaligned example, the longer reflected rays 28 converge to a location on the image 30 having a value of X between 0 and 1. Similarly, the shorter rays 28 are directed to a location having an X value greater than 1. However, the location differential between reflected off-center rays 28 and the aligned reflected rays 16 that reflect from the upper end 13 is greater than the location differential of those rays reflecting from the lower end 15. This concentrates more light energy in the middle portion of the image 30 than in the image 18. Moreover, the additional concentrated energy from the distorted image 30 may also exceed operational limits of the solar cell. Either image 24, 30 can have localized increased flux densities that may be damaging to a solar cell or its associated hardware (e.g. wiring). Accordingly, a need exists for a solar collection system that can operate in situations of misalignment between the solar collector 12 and source of the incoming rays.

### SUMMARY OF THE INVENTION

Disclosed herein are example embodiments of a solar collector for concentrating reflected solar energy into an image that is converted into electricity. In one embodiment, the collector is configured so that solar energy reflecting from regions of the collector farthest from the image is directed towards the middle region of the image. Alternatively, in another embodiment, one or more segments of the collector can be configured to form a corresponding discrete portion of the image; the solar energy forming the portion of the image can be inverted from the solar energy reflecting from the one or more segments. Optionally, the portions created by the one or more segments can overlap.

### BRIEF DESCRIPTION OF THE DRAWINGS

Some of the features and benefits of the present invention having been stated, others will become apparent as the description proceeds when taken in conjunction with the accompanying drawings, in which:

FIG. 1 is a side perspective view of a prior art solar collector and example images formed based on alignment of the collector with the sun.

FIG. 2 is a side view of an example of a solar collector and corresponding reflected image in accordance with the present disclosure.

FIG. 3 is a perspective view of the solar collector and image of FIG. 2.

FIG. 4A is a view of an example of an image formed by the collector of FIG. 1 and FIG. 4B is a view of the image formed by the collector of FIGS. 2 and 3, with both collectors at a 0° tilt angle.

FIG. 5A is a view of an example of an image formed by the collector of FIG. 1 and FIG. 5B is a view of the image formed by the collector of FIGS. 2 and 3, with both collectors at a 0.5° tilt angle in the X direction.

FIG. 6A is a view of an example of an image formed by the collector of FIG. 1 and FIG. 6B is a view of the image formed by the collector of FIGS. 2 and 3, with both collectors at a −0.5° tilt angle in the X direction.

FIG. 7A is a view of an example of an image formed by the collector of FIG. 1 and FIG. 7B is a view of the image formed by the collector of FIGS. 2 and 3, with both collectors at a 0.5° tilt angle in the Y direction.

FIG. 8A is a view of an example of an image formed by the collector of FIG. 1 and FIG. 8B is a view of the image formed by the collector of FIGS. 2 and 3, with both collectors at a 0.5° tilt angle in the X direction and 0.5° tilt angle in the Y direction.

FIG. 9A is a view of an example of an image formed by the collector of FIG. 1 and FIG. 9B is a view of the image formed by the collector of FIGS. 2 and 3, with both collectors at a −0.5° tilt angle in the X direction and 0.5° tilt angle in the Y direction.

FIG. 10A is a view of an example of an image formed by the collector of FIG. 1 and FIG. 10B is a view of the image formed by the collector of FIGS. 2 and 3, with both collectors at a −0.5° tilt angle in the Y direction.

FIG. 11A is a view of an example of an image formed by the collector of FIG. 1 and FIG. 11B is a view of the image formed by the collector of FIGS. 2 and 3, with both collectors at a 0.5° tilt angle in the X direction and −0.5° tilt angle in the Y direction.

FIG. 12A is a view of an example of an image formed by the collector of FIG. 1 and FIG. 12B is a view of the image formed by the collector of FIGS. 2 and 3, with both collectors at a −0.5° tilt angle in the X direction and −0.5° tilt angle in the Y direction.

FIG. 13 is a schematic of a solar conversion circuit.

FIG. 14 is a perspective view of an example array of the collectors of FIGS. 2 and 3.

It will be understood the improvement described herein is not limited to the embodiments provided. On the contrary, the present disclosure is intended to cover all alternatives, modifications, and equivalents, as may be included within the spirit and scope of the improvement as defined by the appended claims.

### DETAILED DESCRIPTION OF THE INVENTION

The present invention will now be described more fully hereinafter with reference to the accompanying drawings in which embodiments of the invention are shown. This invention may, however, be embodied in many different forms and should not be construed as limited to the illustrated embodiments set forth herein; rather, these embodiments are provided so that this disclosure will be thorough and complete, and will fully convey the scope of the invention to those skilled in the art. Like numbers refer to like elements throughout. For the convenience in referring to the accompanying figures, directional terms are used for reference and illustration only. For example, the directional terms such as “upper”, “lower”, “above”, “below”, and the like are being used to illustrate a relational location.

It is to be understood that the invention is not limited to the exact details of construction, operation, exact materials, or embodiments shown and described, as modifications and equivalents will be apparent to one skilled in the art. In the drawings and specification, there have been disclosed illustrative embodiments of the invention and, although specific terms are employed, they are used in a generic and descriptive sense only and not for the purpose of limitation.

Described herein are example systems and methods of converting solar energy to electricity. In one exemplary embodiment, a system uses a collector that concentrates collected solar energy in an image that is offset from the collector midpoint. Additional embodiments described herein include collectors that reflect and concentrate light within a portion of a plane that coincides with a surface of a solar cell. One example embodiment includes a solar collector that forms a beam of concentrated light that does not mirror the collector surface. That is, at least some of the rays reflecting from the reflective surface of the collector travel along a path that intersects the path of one or more other reflected rays. One example of a solar collector system 40 described herein is shown in a side partial sectional view in FIG. 2. The solar collector system 40 of FIG. 2 includes a curved collector 42 (which may also be referred to as a reflector) having on its rear or non-reflective side a contoured rear surface 44 and on an opposite side a contoured front reflective surface 46. The collector 42 as shown includes segments along its length, wherein the different segments directed reflected rays in a different arrangement. An X-Z axis is shown for reference purposes with coordinates provided at opposite ends of the collector 42. An upper end 49 of the collector 42 is shown having coordinates (0,1) and a lower end 51 is shown with coordinates (1,0). Thus, values of X increase along the collector 42 when traveling from the upper end 49 to the lower end 51 and values of Z correspondingly decrease.

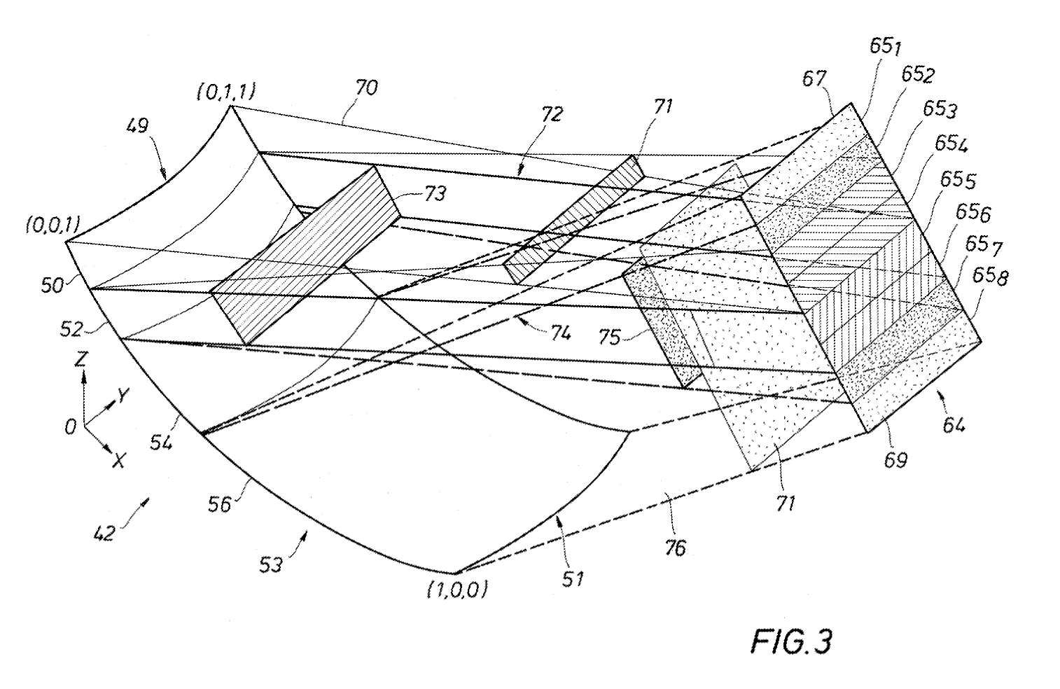

Referring now to FIG. 3, an example embodiment of the collector 42 is shown in a perspective view. An X-Y-Z coordinate axis and Origin O is provided along with representative coordinates at corners of the collector 42. In an exemplary embodiment, the width of the collector 42 is defined as the spatial distance along the Y axis of FIG. 3. The length can be referred to as the distance along a lateral edge 53 of the collector 42 between the upper end 49 and lower end 51 and in a direction transverse to the Y axis. It should be pointed out that in the example embodiment of FIG. 3; the collector 42 has a curved configuration. Therefore, the actual width of the collector 42 when taken along its surface exceeds its spatial placement along the Y axis. Similarly, the collector 42 is contoured in a direction transverse to the Y axis so that spatial displacement in that direction along the collector 42 may not be the same as the actual length of the collector 42 directly along its surface. For the purposes of discussion herein, a spatial difference is referred to as an apparent distance. For example, the coordinates provided on FIG. 3 assess a unit value of 1 as the spatial distance between opposing corners of the collector 42 on its upper end 49. However, measuring the actual length along the surface of the collector 42 between these two corners will provide a value greater than 1 due to the curvature along the upper end 49. Measuring the distance of the lateral edge 53 provides a value of actual length of the collector 42 and not an apparent length.

The embodiment of the collector 42 of FIGS. 2 and 3 includes an upper segment 50, an intermediate upper segment 52, a middle segment 54 and lower segment 56; where the segments 50, 52, 54 56 have a substantially constant length across the collector 42. In an exemplary example, the upper segment 50 is defined as the portion of the collector 42 along the upper end 49 and across the width of the collector 42. In the embodiment illustrated in FIGS. 2 and 3, the respective lengths of the upper segment 50 and intermediate upper segment 52 along the lateral edge 53 are substantially the same. Also in the embodiment illustrated in FIGS. 2 and 3, the length of the middle segment 54 is greater than the lengths of both the upper segment 50 and intermediate upper segment 52; but less than the length of the lower segment 56. In one example, the middle segment 54 has twice the length of the upper segment 50 and half the length of the lower segment 56.

Referring now to the embodiment illustrated in FIG. 2, an example of a forward collector 58 is shown facing the reflective surface 46 side of the collector 42 and having an exemplary embodiment of a receiver 60 mounted thereon. The receiver 60 illustrated in FIG. 2 is positioned so that concentrated light reflected from the collector 42 coincides with an example solar cell 62 on the rearward-facing surface of the receiver 60. An exemplary embodiment of an image 64 is illustrated aligned on the solar cell 62, in this example the image 64 is formed by light rays reflecting from the collector 42. The image 64 depicted is subdivided into discrete image segments 65₁₋ₙ. As will be described in more detail below, in an example, the different segments 50, 52, 54, 56 of the collector 42 direct reflected concentrated solar energy onto one or more of the image segments 65₁₋ₙ. In the example of FIG. 3, there are eight segments 65, thus n=8. The image 64 includes an upper end 67 along an outer peripheral side of the segment 65₁ and a lower end 69 along an outer peripheral side of the segment 65₈. For the purposes of reference herein, the length of the image 64 is the distance between the upper and lower ends 67, 69.

In the example embodiment of FIG. 2, solar rays 68 are shown bearing towards the reflective surface 46 of the collector 42. Reflections of the solar rays 68 from the segments 50, 52, 54, 56 are collectively illustrated as beams. An exemplary embodiment of a beam 70 is shown reflecting from the upper segment 50 to form at least a portion of the segments 65₃ and 65₄ of the image 64 of FIG. 3. Additionally, the beam 70 is inverted, that is, the rays from the upper portion of the upper segment 50 form the lower portion of the segment 654. More specifically, the rays from the upper segment 50 that originate adjacent the upper edge 49, are directed to the portion of the segment 65₄ adjacent segment 65₅. Similarly, the rays originating from the portion of the upper segment 50 adjacent the upper intermediate segment 52, are directed towards the portion of the segment 65₃ bordering segment 65₂. Thus, the upper segment 50 is configured so that rays reflecting from its upper portion (upper rays) make up the lower portion of the beam 70 at the image 64. Further to this example, rays reflecting from the lower portion of the upper segment 50 are directed towards the image 64 above where the upper rays are directed. As will be understood by those skilled in the art, the example of the collector 42 depicted is configured so that rays reflecting from its upper portion are directed proximate the mid portion of the image 64. The inverted beam 70 has a cross-section 71 that varies with distance from the collector 42. Shown in the exemplary example of FIG. 2, the cross section 71 has a linearly decreasing width (distance along the Y axis) and a height (distance transverse to the Y axis) that reduces to a minimum point where the rays cross and then increases substantially linearly to where it forms the portion of the image 64.

The embodiment of the upper intermediate segment 52 shown in FIGS. 2 and 3 casts a beam 72 along a path somewhat parallel to the general path followed by the beam 70. The rays forming the beam 72, while concentrated, remain substantially adjacent and generally follow paths that do not cross. Therefore, the beam 72 is not inverted but resembles a mirror image of the upper intermediate segment 52 and shown directed to segments 65₅ and 65₆. The beam 72 is shown having a the cross section 73, wherein the width and height of the cross section 73 decreases linearly with distance as the beam 72 approaches the image 64 from the surface of the collector 42.

As shown in the embodiments of FIGS. 2 and 3, the lower segment 56 reflects rays that form a beam 74 shown inverted similar to the beam 70. Referring to the example embodiment illustrated in FIG. 3, the beam 74 coincides with the image 64 from image segment 65₂ through image segment 65₇. The lower segment 56 is configured to reflect solar rays that form a beam 76 that mirrors the lower segment 56 and is superimposed over the entire image 64 from image segment 65₁ through image segment 65₈. Thus in an example embodiment, image segments 65₃ and 65₄ are made up of light reflected from the upper intermediate segment 52, the middle segment 54, and the lower segment 56; image segments 65₃ and 65₆ are made up of light reflected from the upper segment 50, the middle segment 54, and the lower segment 56; image segments 65₂ and 65₇ are made up of light reflected from the middle segment 54 and the lower segment 56; and image segments 65₁ and 65₈ are made up of light reflected from only the lower segment 56.

In the example embodiment of the collector 42 in FIGS. 2 and 3, the upper edge 49 is the portion of the collector 42 farthest from the image 64. Accordingly, the rays and beams of reflected solar energy from the furthest portion are most likely to distort or change location along the beam 64 in response to misalignment between the sun's rays and the collector 42. Thus, by forming a collector 42 that directs concentrated solar energy from its furthest reflective region towards the middle portion of the image 64, orientation misalignments can be better tolerated without a resulting reduction in collected solar energy. In one example embodiment, the middle portion of the image 64 can be halfway between the upper and lower ends 67, 69, can be a region adjacent to or superimposed over halfway between the upper and lower ends 67, 69 that extends some distance past one or both sides of halfway, where the distance may include from about 10% to about 75% of the length of the image 64, and all values between.

### EXAMPLE

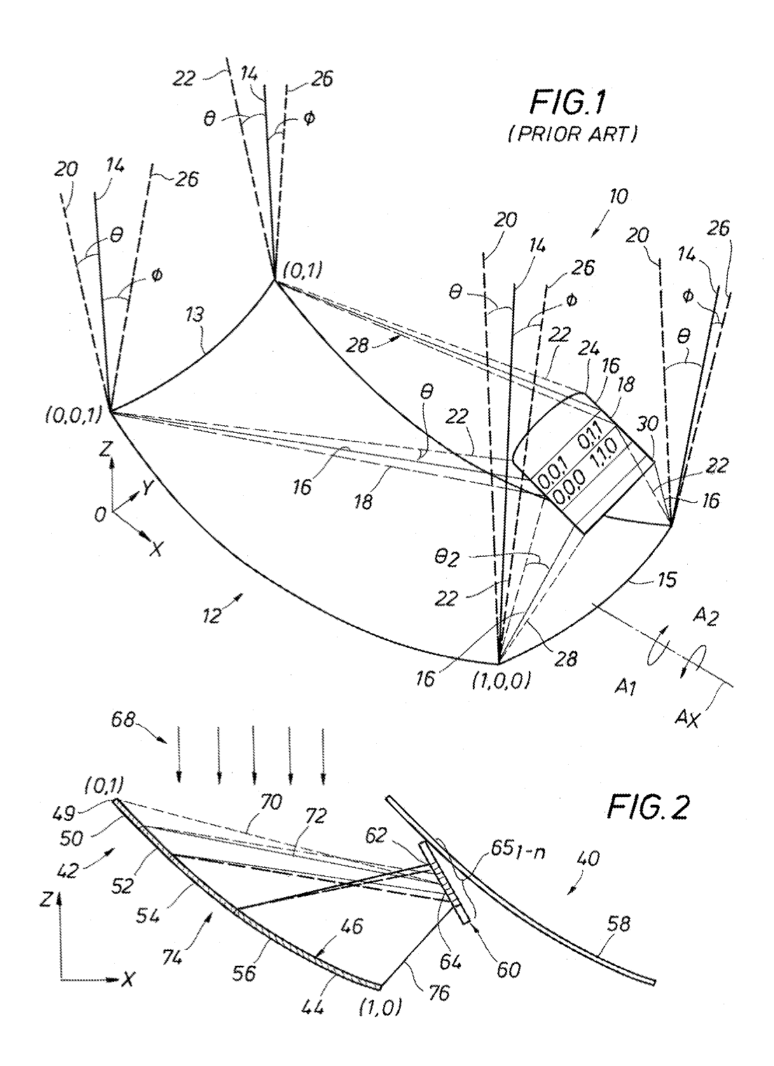

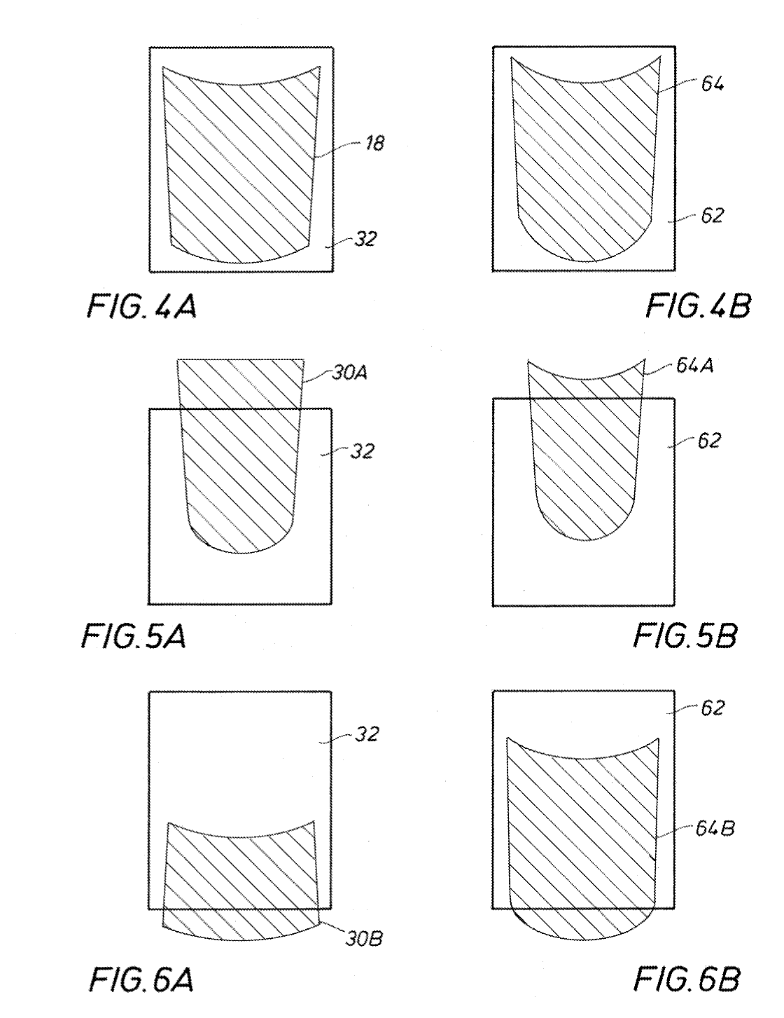

In one non-limiting example, MATHCAD® software was used to simulate reflective images for the collector 12 of FIG. 1 and the collector 42 of FIGS. 2 and 3. For both collectors 12, 42, the simulated images had an area of 8 mm² to coincide on a 10 mm² solar cell. Simulated images were created for both collectors 12, 42 assuming full alignment with the sun; additional simulated images were created for misaligned situations at various angles of tilt along one or both of the X and Y axis. Flux energies and maximum flux of the simulated images were calculated. Shown in FIGS. 4A through 12A are the simulated images formed by the collector 12 of FIG. 1; FIGS. 4B through 12B represent the simulated images formed by the collector 42 of FIGS. 2 and 3.

Specifically, with reference to FIG. 4A, an aligned image 18 is shown directed on an upper surface of a solar cell 32. In this example, the collector 12 (FIG. 1) is in alignment with the sun with a zero tilt angle in the X and Y direction. Similarly, in FIG. 4B, the collector 42 (FIGS. 2 and 3) is aligned to project the image 64 directly onto the cell 62, also having a zero tilt angle in the X and Y direction. FIGS. 5A and 5B illustrate an example where the collectors 12, 42 are tilted at 0.5° along the X axis. Referring back to FIG. 1, this would result in a value of 0.5° for the angle θ. The image 30A in FIG. 5A extends above the surface of the cell 32. Similarly, the image 64A shown in FIG. 5B also has a portion extending past the outer edges of the solar cell 62. In this example, the energy of image 30A is 81.5% of image 18, whereas the energy of image 64A is 82.1% of the energy of image 64. As noted above, misalignment between a light source (the sun) and a collector can distort a reflected image with varying flux values. Also simulated was the ratio of lowest value of flux within the image to the highest value of flux in the image (maximum flux level). The flux values were normalized, so that flux values would be equal to 1 for an image having equal flux distribution. Referring now to FIGS. 5A and 5B, the maximum flux level is 2.588 for image 30A and 1.92 for image 64A.

FIGS. 6A and 6B illustrate an off axis alignment of negative 0.5° in the X axis. This can be illustrated as the incoming rays in the direction of an angle Φ from aligned array 14. (FIG. 1). In this example, a portion of both images 30B, 64B extends below the solar cells 32B, 62B. However, the image 30B, due to the disparity in length of reflecting rays discussed above, has a height noticeably reduced over that of the height of the image 64B. In this example, the energy of the image 30B is 88.6% of the energy of the image 18, whereas the energy of the image 64B is 89.4% of the energy of the image 64. The maximum flux level is 4.729 for image 30B and 1.991 for image 64B.

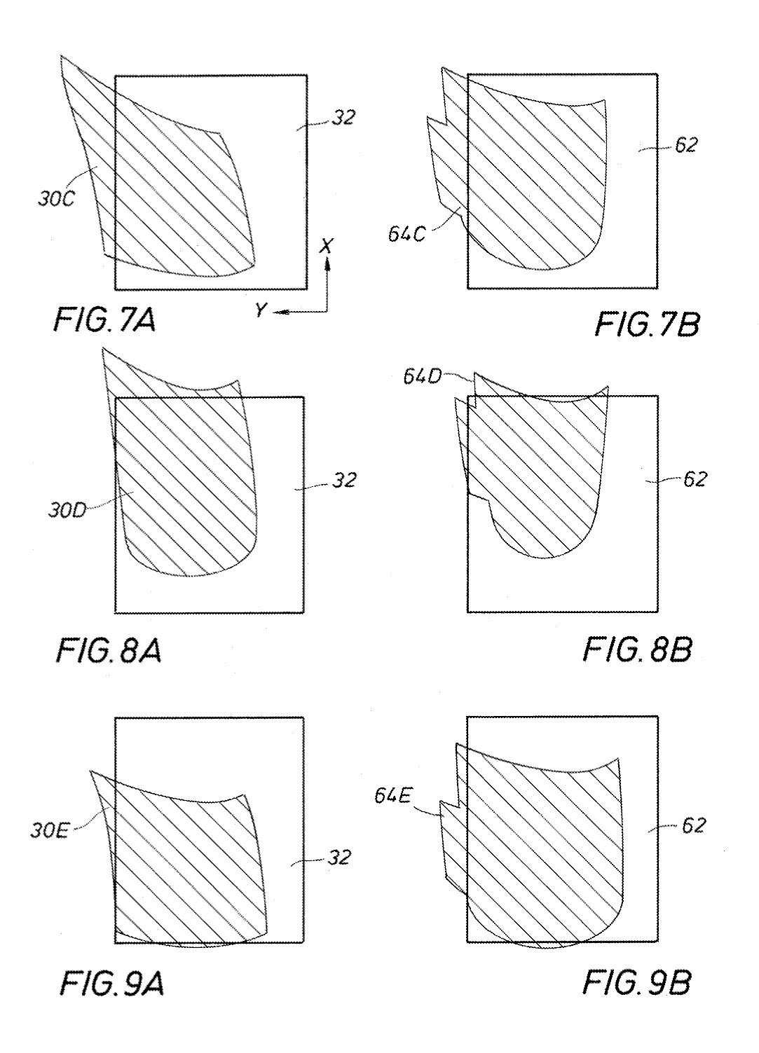

In FIGS. 7A and 7B an X-Y coordinate axis is shown correlating to the X and Y axis of FIGS. 1 through 3. Also provided is a reference axis A_{X} in FIG. 1 that bisects the width of the collector 12 in a direction parallel to the X axis. Thus, a rotation in the Y axis tilts the collector 12 about this axis A_{X}. A positive rotation is illustrated by a curved arrow A₁ (FIG. 1) and negative rotation is illustrated by oppositely directed curved arrow A₂ (FIG. 1). In FIGS. 7A and 7B, images 30C and 64C were obtained by simulating a 0.5° tilt of the collectors 12, 42 on the Y axis. Images 30C and 64C each have a portion extending past their respective solar cells 32, 62 in a direction of an increasing value of Y. In the example of a 0.5° tilt in the positive Y axis, the energy of the image 30C from collector 12 is 83.6% of image 30 and the energy of image 64C is 84.1% of the energy of image 64. The maximum flux level is 1.549 for image 30C and 1.728 for image 64C.

FIGS. 8A and 8B represent rotating the collectors 12, 52 an angle of 0.5° in both the X and Y axis. As shown in FIGS. 8A and 8B, the images 30D, 64D extend past the edges of the solar cells 32, 62 in directions of increasing X and increasing Y. The energy of image 30D is 88.4% of image 30 and the energy of image 64D is 96.7% of the energy of image 64. The maximum flux level is 1.938 for image 30D and 1.92 for image 64C.

FIGS. 9A and 9B illustrate an example of a negative 0.5° tilt in the X direction of the collectors and a positive 0.5° tilt in the Y direction. Both images 30E and 64E extend past the cells 32, 62 in regions of increasing Y but decreasing X. The energy of 30E is 93.4% of the energy of image 30 and the energy of image 64E is 95.3% of image 64. The maximum flux level is 2.347 for image 30E and 1.778 for image 64E.

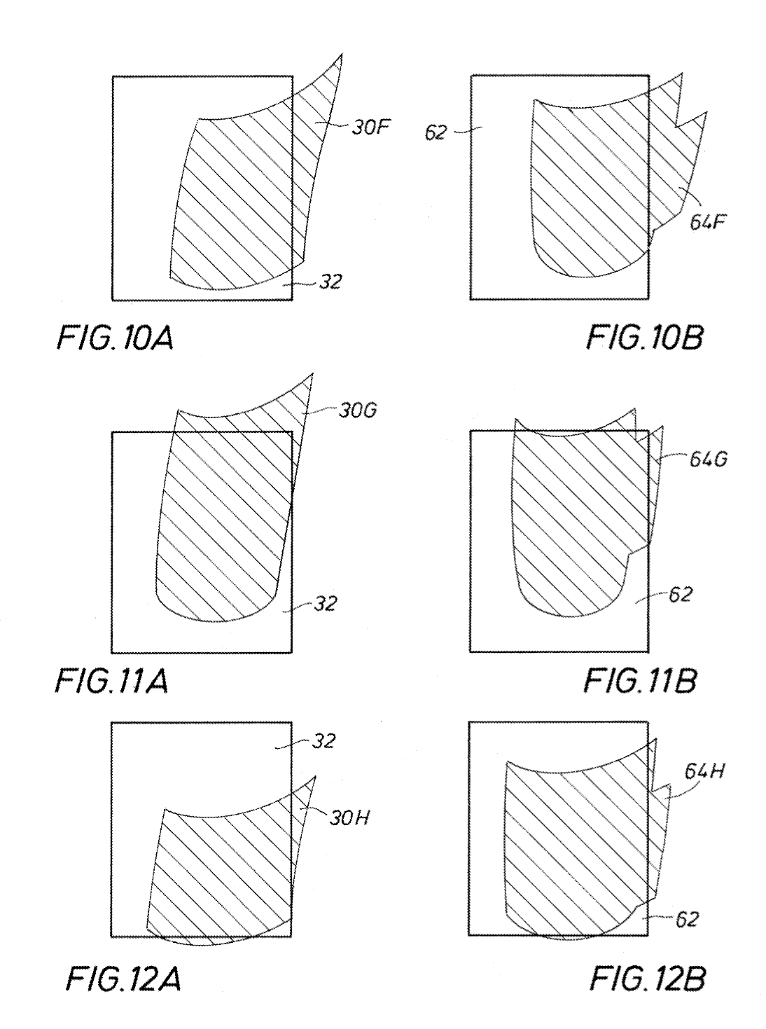

FIGS. 10A and 10B illustrate a 0° tilt in the X direction and a −0.5° tilt in the Y direction, wherein both images 30F and 64F extend past the cells 32, 62 in a region of decreasing values of Y. The energy of image 30F is 83.6% of image 30 and the energy of image 64F is 84.1% of image 64. The maximum flux level is 1.532 for image 30F and 1.639 for image 64F. FIGS. 11A and 11B represent images formed by a 0.5° tilt in the X direction and −0.5° tilt in the Y direction. Thus, in this situation, the images 30G and 64G extend past the cells 32, 62 and areas of increasing X and decreasing Y. The energy of image 30G is 88.4% of image 30 and the energy of image 64G is 96.7% of image 64. The maximum flux level is 1.938 for image 30F and 1.92 for image 64F.

Referring now to FIGS. 12A and 12B, in this situation, the collectors 12 and 42 were simulated in a tilt angle of negative 0.5° for both the X and Y axis. Thus, the images 30H, 64H extend off of the cells 32, 62 and areas of decreasing values of X and Y. The energy of image 30H is 93.4% of image 30 and the energy of image 64H is 95.3% of image 64. The maximum flux level is 2.347 for image 30F and 1.76 for image 64F. Accordingly, it can be seen through the various tilt angles of the collectors to represent misaligned configurations, that by directing the reflected rays from portions of an off axis collector further away from the produced concentrated image towards the center of the image can result in greater energy recovery over various off tilt angles. Moreover, the value of maximum flux is maintained at a more consistent level thereby reducing the chances of damaging the solar cell.

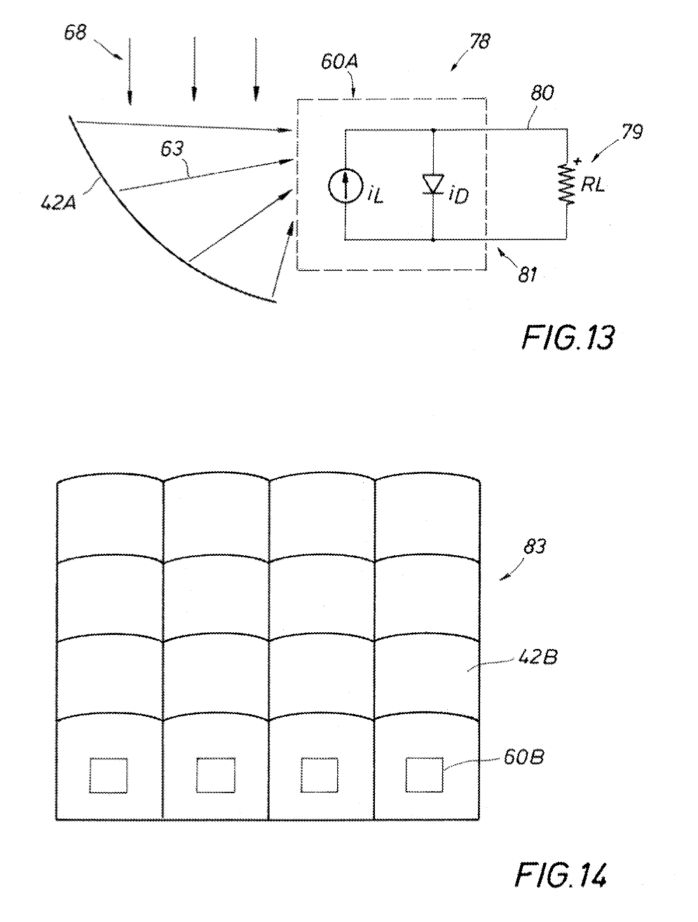

An exemplary example of a solar conversion system 78 is shown schematically in FIG. 13. In this example the solar conversion system 78 includes a collector 42A, a receiver 60A, and a resistive load 79 in electrical communication with the receiver 60A. Conductive members 80 connect the load 79 to the receiver 60A forming a circuit 81. The receiver 60A is schematically represented as a circuit having a current source with current i_{L} in parallel with a diode having current i_{D}. The circuit 81 is coupled to the receiver module 60A by the conductive members 80 to the resistive load 79; that may be any device that operates on or otherwise runs on or draws an electrical current or voltage, as well as any device or system for the storage of electrical current power or voltage. In an example of operation, sun rays 68A reaching the collector 42A reflect from the collector 42A to form reflected rays 63. The within the module 60A is a conversion cell (not shown) that converts the solar energy of the focused reflected rays 63 to electricity that is communicated to the resistive load 79 through the conductive members 80. Shown in perspective view in FIG. 14 is an example of an array 83 formed by arranging a plurality of collectors 42B and their respective modules 60B.

The present invention described herein, therefore, is well adapted to carry out the objects and attain the ends and advantages mentioned, as well as others inherent therein. While a presently preferred embodiment of the invention has been given for purposes of disclosure, numerous changes exist in the details of procedures for accomplishing the desired results. These and other similar modifications will readily suggest themselves to those skilled in the art, and are intended to be encompassed within the spirit or the present invention disclosed herein and the scope of the appended claims. While the invention has been shown in only one of its forms, it should be apparent to those skilled in the art that it is not so limited but is susceptible to various changes without departing from the scope of the invention.

1. A system to convert solar energy to electricity, the system comprising:
a solar cell; and
a solar collector having a reflective front surface configured to have segments that are each a different distance away from the solar cell, so that when electromagnetic energy contacts the front surface, the electromagnetic energy reflects away from each segment and converges on the solar cell to form a concentrated image having a middle portion made up of electromagnetic energy reflecting away from a segment that is farther away from the image than another segment and so that electromagnetic energy reflecting away from at least two of the segments generally follows paths that cross one another.

2. A system as defined in claim 1, wherein the segment that is farther away from the image than another segment defines a first segment.

3. A system as defined in claim 2, wherein the solar collector includes a second segment on the reflective surface that is adjacent the first segment, and wherein the electromagnetic energy reflecting from the first segment is directed to a first portion of the image and wherein electromagnetic energy reflected from the second segment is directed to a second portion of the image that is adjacent the first portion.

4. A system as defined in claim 3, wherein the area of the first segment is substantially the same as the area of the second segment.

5. A system as defined in claim 3, wherein the first and second portions define a mid-portion and wherein the solar collector includes a third segment on the reflective surface that is adjacent the second segment and on a side opposite the first segment, wherein electromagnetic energy reflecting from the third segment superimposes the mid portion and forms at least a portion of the image on opposing ends of the mid portion, and wherein the electromagnetic energy reflecting from the first segment is inverted.

6. A system as defined in claim 1, wherein the solar collector comprises a second segment on the reflective surface that is adjacent the first segment and a third segment on the reflective surface that is adjacent the second segment on a side opposite the first segment wherein the area of the third segment is about two times the area of the first segment.

7. A system as defined in claim 5, wherein the solar collector includes a fourth segment on the reflective surface that is adjacent the third segment and on a side opposite the second segment, wherein solar energy from the fourth segment superimposes substantially the entire image.

8. A system as defined in claim 1, wherein the solar collector comprises a second segment on the reflective surface that is adjacent the first segment, a third segment on the reflective surface that is adjacent the second segment on a side opposite the first segment, and a fourth segment on the reflective surface that is adjacent the third segment on a side opposite the second segment wherein the area of the fourth segment is about four times the area of the first segment.

9. A system as defined in claim 1, further comprising an electrical load in electrical communication with the solar cell.

10. A system as defined in claim 1, further comprising a plurality of solar collectors and associated solar cells formed into an array.

11. A system as defined in claim 1, wherein the collector is profiled so that when the electromagnetic energy reflects from the collector the energy converges into the concentrated image at a location offset from the midpoint of the collector.

12. A method of converting light into electricity comprising:
(a) forming an image of concentrated light by reflecting light from a reflective surface of a solar collector;
(b) orienting the solar collector to position the image of concentrated light onto a solar cell that is offset from an axis of the solar collector and so some region of the reflective surface is farther away from the solar cell than another region of the reflective surface; and
(c) reflecting light from at least a portion of the region of the reflective surface farther away from the solar cell onto the middle portion of the image.

13. A method as defined in claim 12, further comprising inverting the reflected light of step (c).

14. A method as defined in claim 12, wherein the reflective surface has lateral edges on opposing sides of the surface, the method further comprising partitioning the reflective surface into sections that extend between the lateral edges, defining the region of step (c) as a first segment, defining the portion of the image having light reflected from the first segment as a first section, and defining a second segment adjacent the first segment that is closer to the solar cell than the first segment, wherein light reflecting from the second segment is directed onto the image to form a second section that is adjacent the first section to form a middle section of the image.

15. A method as defined in claim 14, further comprising defining a third segment of the collector that is adjacent the second segment and closer to the solar cell than the second segment, and directing light reflected from the third segment onto substantially the entire image.

16. A method as defined in claim 14, further comprising defining a third segment of the collector that is adjacent the second segment and closer to the solar cell than the second segment, and directing light reflected from the third segment that is on the middle segment and at least a portion of the image adjacent the middle section of the image.

17. A method as defined in claim 16, further comprising defining a fourth segment of the collector that is adjacent the third segment and closer to the solar cell than the third segment, and directing light reflected from the fourth segment onto substantially the entire image.

18. A method as defined in claim 12, further comprising powering a load by providing electrical communication between the solar cell and the load.

19. A solar conversion system comprising:
a solar cell; and
a solar collector having a reflective surface and disposed with some portion of the solar collector farther away from the solar cell than another portion of the solar collector, so that when the solar collector is in the path of rays from the sun, the rays reflect from the reflective surface and converge into an image of concentrated solar energy on the solar cell and the rays reflecting from the portion of the solar collector farther away from another portion of the solar collector form at least a portion of the middle portion of the image.

20. The solar conversion system of claim 19, wherein the rays reflecting from the farther away portion of the solar collector are inverted and follow a path that intersects a ray reflecting from another portion of the solar collector.
